(19) United States
(12) Patent Application Publication
(10) Pub. No.: US 2005/0189953 A1
(43) Pub. Date: Sep. 1, 2005

(54) Method for measuring the moisture of silage as it is harvested

(75) Inventors: Kurt Stehr, Baldwin, WI (US); Barry Serier, Baldwin, WI (US)

Correspondence Address: HARVEST TEC, INC., P.O BOX 63, HUDSON, WI, 54016, US

(73) Assignee: HARVEST TEC< INC.

(21) Appl. No.: 10/307,553

(22) Filed: Dec. 2, 2002

(51) Int. Cl. G01R 27/08

(52) U.S. Cl. 324/695; 324/694

(57) ABSTRACT

The method that has been invented, uses the differences in electrical conductivity based on moisture content of corn or hay silage, to measure the moisture of the crop while it is being harvested. Direct current voltage is supplied to one of two electrodes mounted in the forage harvesting implement in a specific locations and then either grounded to or conducted to a second electrode.

### SUMMARY OF THE INVENTION

The method that has been invented sends direct current electricity from one electrode through freshly chopped silage crops while they are being harvested to a second electrode, measuring the electrical conductivity of the crop. This conductivity value correlates closely to the moisture content of the crop when two key conditions are met regarding the location of the electrodes: 1. Both electrodes are positioned in the flow of crop downstream from a cutting device that is normally part of a forage harvesting implement, so that they are in contact with crop that is cut to a consistent length; 2. Both electrodes are positioned downstream from the accelerating device that is normally part of a forage harvesting implement, so that they are in contact with a continuous flow of crop traveling at a fixed velocity.

### BACKGROUND OF THE INVENTION

Feed crops including corn, hay and small grains are harvested with forage-harvesting implements and stored in oxygen-limiting structures to allow for fermentation to take place. Fermented crops will store without spoilage and are attractive to livestock so the level of consumption by the livestock is improved. In order for fermentation to occur, the range of moisture at harvest must be maintained between 45% and 65% water content so that there is the proper amount of moisture for the bacteria that cause fermentation to activate. During field harvesting conditions, moisture content varies due to conditions affecting drying rate of the crop: crop consistency, climatic conditions and ground moisture condition. Operators of the harvesting implements have taken samples of the crop being harvested and run moisture content tests on stationary moisture testing devices to monitor harvesting moistures as closely as possible.

Moisture testing devices mounted on baling equipment have been in common use providing continuous readings of moisture to operators during the harvesting process generally operated in the 10% to 30% moisture range. Many of these testers use two electrodes and measure the conductivity between them, through the bale as a means to determine moisture content. The electrodes on these devices are in contact with tightly packed crop after the bale has been formed. In bales above 40% moisture content, the conductivity does not increase a measurable amount. With a high end of moisture reading of 40%, these devices have not proven useful for the harvest of silage with electrodes mounted on forage harvesting implements in a fashion similar to the way there are mounted in a baling implement.

### SPECIFICATIONS

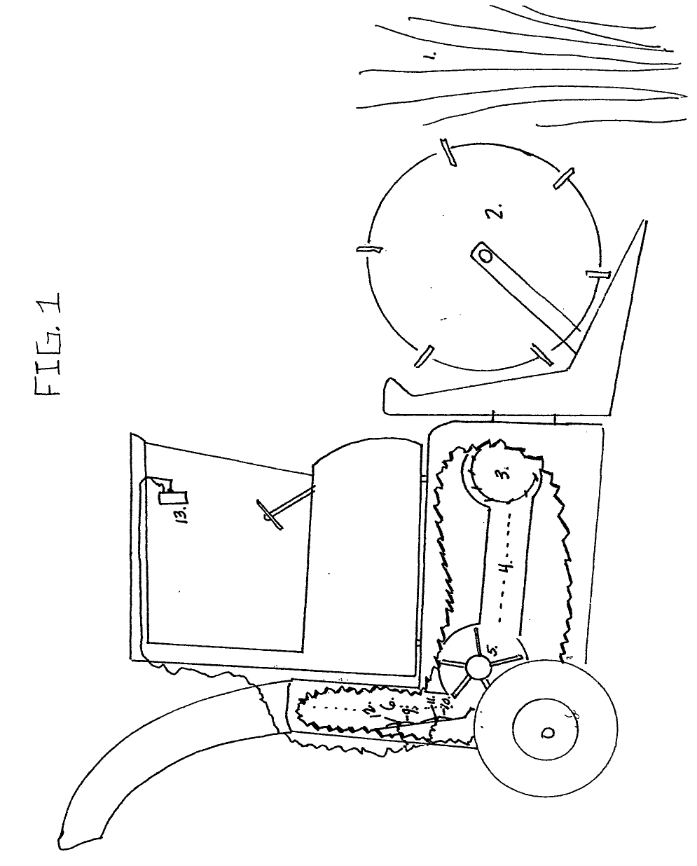

The method that has been invented relates to the harvest of silage crops with a forage harvester FIG. 1. A crop 1 is either cut or picked up from a windrow off the ground. A feeding device 2 delivers the crop material to a cutting device 3, which cuts the crop to a consistent length between ½ and 1 inch. The crop in area 4 is now a consistent length, but the velocity of crop in this area is dependent on the amount of crop flow coming from the feeing device 2. An accelerator 5 is positioned to pick-up the crop flow and increase velocity in area 6 so that he crop can be discharges thru 7 and have enough momentum to reach a holding area 8. Velocity of the crop is increased from an in-flow speed of between 2 and 10 feet per second in area 4 to 150 to 300 feet per second in area 6. Therefore in area 6 the crop now is a consistent length and is moving at a consistent velocity.

Utilizing these two factors of consistency, accurate moisture readings can be attaining using the resistance of the crop in area 6. Two electrodes 9 and 10 are placed in the implement in an area where contact with the crop is as constant as possible. The electrodes are isolated from the frame of the implement with non-conductive members 11 and 12. Direct current voltage is sent from a control 13 to either of the electrodes 9 or 10. The alternate electrode is connected to a reading device inside the control 13 that reads the voltage conducted from one electrode to another. This reading is scaled and displayed as moisture content. An example of the scaling for measuring the moisture of hay silage where 10 volts of direct current are fed into one electrode and then read off the other is

| Voltage-reading | moisture content displayed |
|---|---|
| 10.0 | 80% |
| 9.716 | 78% |
| 9.700 | 76% |
| 9.661 | 74% |
| 9.619 | 72% |
| 9.560 | 70% |
| 9.500 | 68% |
| 9.433 | 66% |
| 9.384 | 64% |
| 9.315 | 62% |
| 9.253 | 60% |
| 9.160 | 58% |
| 9.073 | 56% |
| 8.976 | 54% |
| 8.872 | 52% |
| 8.747 | 50% |
| 8.600 | 48% |
| 8.450 | 46% |
| 8.300 | 44% |
| 8.130 | 42% |
| 7.270 | 40% |
| 4.640 | 38% |
| 0.323 | 36% |

The voltage values may vary as much a 5% of the voltages above for moistures between 80% and 36% for hay silage depending on the properties of the hay silage being harvested. If a 10-volt circuit is being used in this method, the variation in voltage readings can be up to 0.5 volts from the values above. A means for adjusting the voltage values for the moisture readings can be incorporated into this method, where all values are adjusted at the same correction factor. Or as an alternative, individual entries can be used to adjust voltage values for each moisture level desired.

Corn silage has different properties of conductivity than hay silage. When changing between harvesting hay silage and corn silage, a different scale must be used in this method of determining moisture content. A selector switch or menu can be included with the control 13 so that different values for moisture are assigned to different conductivity values for different types of crops. An example of values for corn silage where 10 volts of DC power is fed into one electrode and read off the other is:

| Voltage reading | moisture content displayed |
|---|---|
| 10.0 | 80% |
| 9.813 | 76% |
| 9.799 | 74% |
| 9.781 | 72% |
| 9.764 | 70% |
| 9.740 | 68% |
| 9.714 | 66% |
| 9.685 | 64% |
| 9.641 | 62% |
| 9.495 | 60% |
| 9.348 | 58% |
| 9.202 | 56% |
| 9.137 | 54% |
| 8.985 | 52% |
| 8.899 | 50% |
| 8.683 | 48% |
| 8.331 | 46% |
| 7.980 | 44% |
| 7.628 | 42% |
| 7.276 | 40% |
| 6.470 | 38% |
| 5.663 | 36% |
| .0659 | 34% |

Again, there will be variation in voltage values for a given moisture depending on the properties of the corn silage being harvested. This variation will be less than 5% for all types of corn silage and the method may include a means for adjusting the voltage readings up to 5% for moistures between 80% and 34%.

An alternative method for associating voltage to moisture is to supply a level of direct current voltage to one electrode and have a second electrode as an isolated ground. Instead of reading the voltage traveling through the crop to a second electrode, the voltage is read on the electrode the power is supplied to. Voltage retained on the electrode varies inversely as the resistance of the crop increases. An example of the scaling for hay silage where 10 volts of direct current are fed into one electrode that is grounded to a second electrode to draw down voltage, and the retained voltage is read is:

| Voltage-reading | moisture content displayed |
|---|---|
| 10.0 | 0% |
| 9.716 | 36% |
| 9.700 | 38% |
| 9.661 | 40% |
| 9.619 | 42% |
| 9.560 | 44% |
| 9.500 | 46% |
| 9.433 | 48% |
| 9.384 | 50% |
| 9.315 | 52% |
| 9.253 | 54% |
| 9.160 | 56% |
| 9.073 | 58% |
| 8.976 | 60% |
| 8.872 | 62% |
| 8.747 | 64% |
| 8.600 | 66% |
| 8.450 | 68% |
| 8.300 | 70% |
| 8.130 | 72% |
| 7.270 | 74% |
| 4.640 | 76% |
| 0.323 | 80% |

An example of the values for corn silage where 10 volts of direct current are fed into one electrode grounded to a second electrode and the retained voltage is read is:

| Voltage reading | moisture content displayed |
|---|---|
| 10.0 | 0% |
| 9.813 | 36% |
| 9.799 | 38% |
| 9.781 | 40% |
| 9.764 | 42% |
| 9.740 | 44% |
| 9.714 | 46% |
| 9.685 | 48% |
| 9.641 | 50% |
| 9.495 | 52% |
| 9.348 | 54% |
| 9.202 | 56% |
| 9.137 | 58% |
| 8.985 | 60% |
| 8.899 | 62% |
| 8.683 | 64% |
| 8.331 | 66% |
| 7.980 | 68% |
| 7.628 | 70% |
| 7.276 | 72% |
| 6.470 | 74% |
| 5.663 | 76% |
| 0.659 | 80% |

If crop builds up around the electrodes, conductivity readings can be affected in two ways.

First, a coating of built-up crop will isolate the electrode from the flow of additional harvested crop, making ongoing readings for moisture invalid. Second, the built-up crop can create a pathway of electrical conductivity between the electrodes and the frame of the harvesting implement. This additional conductivity adds to the conductivity attained from the crop passing by and results in values that are too high for the crop being harvested.

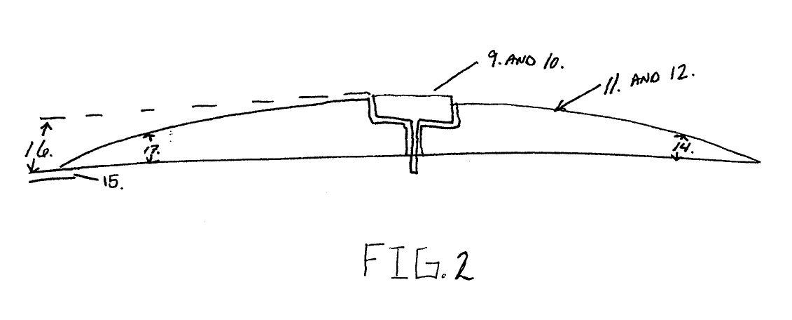

To prevent crop build up around the electrodes 9 and 10, the isolators 11 and 12 can be shaped in such a way so that this build-up does not occur. In a close-up view of an electrode and isolator FIG. 2, the key element of design to prevent build-up in front of the electrode is maintaining a low angle on the ramp up of the leading edge 14 of the isolator 11 and 12. The angle 14 must be less than 12 degrees when maintaining enough height for the electrode 9 and 10 to provide good contact with the crop flow going by.

This height 15 between the top of the electrodes 9 and 10 and the surface of the machine 15 is normally between 0.25 and 1.0 inches 16.

Build-up can also occur on the trailing edge of the electrodes if there is a reduction in velocity of the crop caused by a shadow of the electrode or isolator. Maintaining an angle 17 on the ramp down of the isolator of less than 12 degrees so that air and crop flow behind the isolator is even can prevent the build-up on the backside.

1. A method for determining the moisture content of silage crops where two electrodes are mounted in a silage harvesting implement in a position that is after the crop has been cut to a uniform length and after the velocity of the crop has been accelerated to a consistent speed. Direct current voltage is supplied to one electrode and read off of the other electrode and then scaled for moisture content of the crop and displayed in the cab of the implement.

2. A method as in claim 1 used when harvesting alfalfa hay silage where the voltage plus or minus 5% is scaled to moisture as: 10.0 volts is 80%; 9.716 volts is 78%; 9.700 volts is 76%; 9.661 volts is 74%; 9.619 volts is 72%; 9.560 volts is 70%; 9.500 volts is 68%; 9.433 volts is 66%; 9.384 volts is 64%; 9.315 volts is 62%; 9.253 volts is 60%; 9.160 volts is 58%; 9.073 volts is 56%; 8.976 volts is 54%; 8.872 volts is 52%; 8.747 volts is 50%; 8.600 volts is 48%; 8.450 volts is 46%; 8.300 volts is 44%; 8.130 volts is 42%; 7.270 volts is 40%; 4.640 volts is 38%; 0.323 volts is 36% when 10 volts of direct current is supplied to one electrode and read off a second electrode.

3. A method as in claim 1 used when harvesting corn silage where the voltage plus or minus 5% is scaled to percent moisture as: 10.0 volts is 80%; 9.813 volts is 76%; 9.799 volts is 74%; 9.781 volts is 72%; 9.764 volts is 70%; 9.740 volts is 68%; 9.714 volts is 66%; 9.685 volts is 64%; 9.641 volts is 62%; 9.495 volts is 60%; 9.348 volts is 58%; 9.202 volts is 56%; 9.137 volts is 54%; 8.985 volts is 52%; 8.899 volts is 50%; 8.683 volts is 48%; 8.331 volts is 46%; 7.980 volts is 44%; 7.628 volts is 42%; 7.276 volts is 40%; 6.470 volts is 38%; 5.663 volts is 36%; 0.0659 volts is 34%, when supplying 10 volts of direct current to one electrode and reading the voltage on a second electrode.

4. A method as in claim 1 where the two electrodes are located in isolators with leading edge and trailing edge ramps constructed with less than 12 degrees of incline while the isolator is extending into the flow of crop between 0.25 and 1.0 inches.

5. A method for determining the moisture content of silage crops where two electrodes are mounted in a silage harvesting implement in a position that is after the crop has been cut to a uniform length and after the velocity of the crop has been accelerated to a consistent speed. Direct current voltage is supplied to one electrode and grounded to a second electrode and the retained voltage is read on the electrode to which the power is supplied, and scaled for moisture content of the crop and displayed in the cab of the implement.

6. A method as in claim 5 used when harvesting corn silage where the voltage values plus or minus 5% are scaled to percent moisture as: 10.0 volts is 0%; 9.813 volts is 36%; 9.799 volts is 38%; 9.781 volts is 40%; 9.764 volts is 42%; 9.740 volts is 44%; 9.714 volts is 46%; 9.685 volts is 48%; 9.641 volts is 50%; 9.495 volts is 52%; 9.348 volts is 54%; 9.202 volts is 56%; 9.137 volts is 58%; 8.985 volts is 60%; 8.899 volts is 62%; 8.683 volts is 64%; 8.331 volts is 66%; 7.980 volts is 68%; 7.628 volts is 70%; 7.276 volts is 72%; 6.470 volts is 74%; 5.663 volts is 76%; and, 0.659 volts 80%.

7. A method as in claim 5 used when harvesting hay silage where the voltage values plus or minus 0.5% are scaled to percent moisture as: 10.0 volts is 0%; 9.716 volts is 36%; 9.700 volts is 38%; 9.661 volts is 40%; 9.619 volts is 42%; 9.560 volts is 44%; 9.500 volts is 46%; 9.433 volts is 48%; 9.384 volts is 50%; 9.315 volts is 52%; 9.253 volts is 54%; 9.160 volts is 56%; 9.073 volts is 58%; 8.976 volts is 60%; 8.872 volts is 62%; 8.747 volts is 64%; 8.600 volts is 66%; 8.450 volts is 68%; 8.300 volts is 70%; 8.130 volts is 72%; 7.270 volts is 74%; 4.640 volts is 76%; 0,323 volts is 80%.

8. A method as in claim 5 where the two electrodes are located in isolators with the leading edge and trailing edge ramps constructed with less than 12 degrees of incline while the isolator is extending into the flow of crop between 0.25 and 1.0 inches.
